(19) United States
(12) Patent Application Publication
(10) Pub. No.: US 2005/0139974 A1
(43) Pub. Date: Jun. 30, 2005

(54) Chip package structure

(75) Inventors: Ya-Ling Huang, Kaohsiung City (TW); Hung-Ta Hsu, Ta-Liao (TW); Tzu-Bin Lin, Kaohsiung City (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/023,536

(22) Filed: Dec. 29, 2004

(30) Foreign Application Priority Data
Dec. 31, 2003 (TW) 92137812

(51) Int. Cl. H01L 23/02

(52) U.S. Cl. 257/678

(57) ABSTRACT

A chip package structure is disclosed. The chip package structure includes an inner molding compound with a low modulus and a heat sink covering the chip. An outer molding compound having a modulus larger than the modulus of the inner molding compound can be applied around the heat sink.

### BACKGROUND OF THE INVENTION

1. Field of the Invention

The present invention generally relates to a chip package structure, and more particularly to solve the problem for a chip package structure with a stress loading in the low dielectric constant fabrication process.

2. Description of the Prior Art

In a chip package structure, the molding compound such as QFP (quad flat package), or BGA (ball grid array) used as a package material for preventing the effect of the chip from the outside environment influence and the force impact. The molding material has the strength, hardness, and the physical properties especially for a coefficient of thermal expansion (CTE) to protect the chip to electrically couple other device and would not be affected by the outside environment. However, the properties of the molding material sometime would be damaged the chip, especially the stress problem exists in the molding material and the chip. When the heat sink is placed on the chip to increase the heat dissipation, and the chip operating is under the thermal cycle, such as raised, maintained, or lowered the temperature, and the coefficient of thermal expansion is different between the molding material, heat sink, and the chip, so that the stress variation is an important issue between the molding material, heat sink, and the chip in the packaging process and package structure.

According to abovementioned, the stress problem between the molding material, heat sink, and the chip is more critical when the low dielectric constant (low k) material and the thin wafer is utilized, and the distance between the line width and the device is to be diminished for the performance requirement. Nevertheless, the heat sink would be produced the stress problem, thus, the peeling would be generated between the chip substrate and the wires during the low dielectric (low K) process. The stress problem would be raised when the chip is operating. The coefficient of thermal expansion is large when the material of the heat sink is metal, and the heat sink would be affected after the molding material is filled into the mold to cover the chip, so as to let the molding compound around the chip is split.

### SUMMARY OF THE INVENTION

It is an object of this invention to solve the stress problem which is produced by the heat sink to make the chip and wires peeling in the low dielectric (low k) fabrication.

It is another object of this invention to solve the molding compound around the chip that is to be split after molding process.

According to abovementioned objects, the present invention provides an inner molding compound used to cover the chip, and a heat sink used to cover the inner molding compound to release the stress, so that can be prevented the chip from the outside environment influence and force impact. Furthermore, an outer molding compound further is formed around the heat sink. The modulus, hardness, and the strength for the outer molding compound must be larger than the modulus of the inner molding compound.

Contrast to the prior art and the present invention, the present invention utilized the molding compound with low modulus, and the heat sink covered on the chip, and further an outer molding compound is formed around the heat sink, such that the chip and wires peeling is introduced by the stress of the heat sink would be decreased. Moreover, the present invention also solved the split of the molding compound that is formed around the chip after the molding process.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic representation of showing a heat sink ball grid array (HSBGA) package structure in accordance with the first embodiment of the present invention disclosed herein;

FIG. 2 is a schematic representation of showing a quad flat package (QFP) structure in accordance with the second embodiment of the present invention disclosed herein;

FIG. 3 is a schematic representation of showing a stacked ball grid array (stacked BGA) package structure in accordance with the third embodiment of the present invention disclosed herein;

FIG. 4 is a schematic representation of showing a quad flat package non-leaded package structure in accordance with the fourth embodiment of the present invention disclosed herein;

FIG. 5 is a schematic representation of showing a cavity down ball grid array package structure in accordance with the fifth embodiment of the present invention disclosed herein;

FIG. 6 is a schematic representation of showing a bump chip carrier (BCC) package structure in accordance with the sixth embodiment of the present invention disclosed herein;

FIG. 7 is a schematic representation of showing a flip chip ball grid array (FCBGA) package structure in accordance with the seventh embodiment of the present invention disclosed herein; and

FIG. 8 is a schematic representation of showing a flip chip quad flat non-leaded (FCQFN) package structure in accordance with the eighth embodiment of the present invention disclosed herein.

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

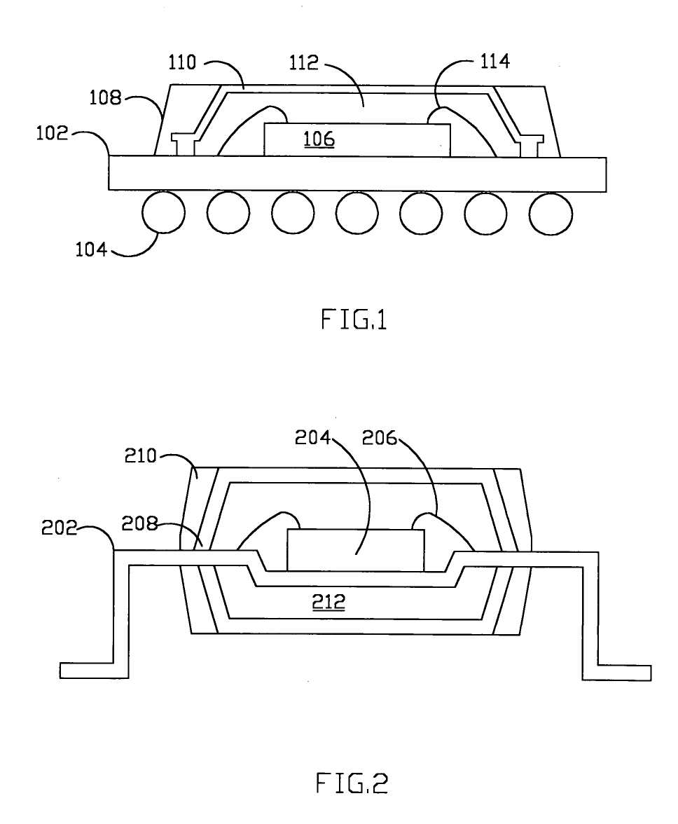

As shown in FIG. 1, represents the first embodiment of the chip package structure of the present invention. FIG. 1 shows a heat sink ball grid array (HSBGA) package structure. The HSBGA package structure utilizes the die attach epoxy or silver glue (not shown) to fix the chip 106 on the board 102. Then, the chip 106 is electrically coupled board 102 with the wires 114 by using wire bonding. The board 102 is electrically coupled with the printed circuit board (PCB) through a plurality of solder balls 104. The board 102 also includes a substrate. The chip 106 includes a first chip that is produced by a low dielectric (low k) fabrication process. The wires 114 can be aluminum (Al) wires or gold (Au) wires.

Then, the inner molding compound is filled into the mold to form an inner molding compound 112 to cover the chip 106 and wires 114. In order to release the stress, the inner molding compound 112 is soft, and has enough elastic modulus that is between 0.4 Mpa and 12 Mpa. Next, an outer molding compound is covered the heat sink 110 on the inner molding compound 112 to form an outer molding compound 108 as shown in FIG. 1. The heat sink 110 includes an Al-heat sink or a Cu-heat sink. The outer molding compound 108 has enough strength, hardness, and the modulus, in which the modulus is between 35000 Mpa and 16000 Mpa, and the material of the outer molding compound is epoxy. The material request for the inner molding compound 112 and the outer molding compound 110 is that the modulus of the outer molding compound 108 is larger than the modulus of the inner molding compound 112. Furthermore, the outer molding compound 108 can be optional in the packaging process. However, the heat sink 110 should be fixed by using the adhesive when the outer molding compound 108 is omitted.

As shown in FIG. 2, represents a second embodiment of the present invention. FIG. 2 shows a quad flat package (QFP) structure. The QFP structure utilizes the die attach epoxy or silver glue to fix the chip 204 on the board 202. The board 202 includes a leadframe. The chip 204 is fixed on the die attached pad of the leadframe by the die attach epoxy or sliver glue. The chip 204 includes a first chip that is produced by the low k fabrication process. Then, the input/output pads are electrically coupled with the pins of the board 202 through multitudes of wires 206 by the wire bonding. The wires 206 can be Al-wires or Au-wires. Next, performing a molding process, the board 202 and the chip 204 are placed into the mold. The inner molding compound 212 is filled into the mold to form an inner molding compound 212 to cover the chip 204 and the board 202. In order to release the stress, the inner molding compound 212 is soft and has enough elastic modulus, in which the material of the inner molding compound 212 is thermal interface material (TIM), and the modulus is between 0.4 Mpa and 12 Mpa. Next, a heat sink 208 is placed outside the inner molding compound 212, in which the heat sink 208 includes an Al-heat sink or a Cu-heat sink. Then, an outer molding compound is formed around the heat sink 208 to form an outer molding compound 210 as shown in FIG. 2. The outer molding compound 210 has enough strength, hardness, and the modulus, in which the modulus is between 35000 Mpa and 16000 Mpa, and the material of the outer molding compound 210 is epoxy. The material request for the inner/outer molding compound (212/210) is that the modulus of the outer molding compound 210 is larger than the modulus of the inner molding compound 212. Furthermore, the outer molding compound 210 can be optional during the packaging process, so the outer molding compound 210 can be omitted. However, the heat sink 208 is fixed by using the adhesive when the outer molding compound 210 is omitted.

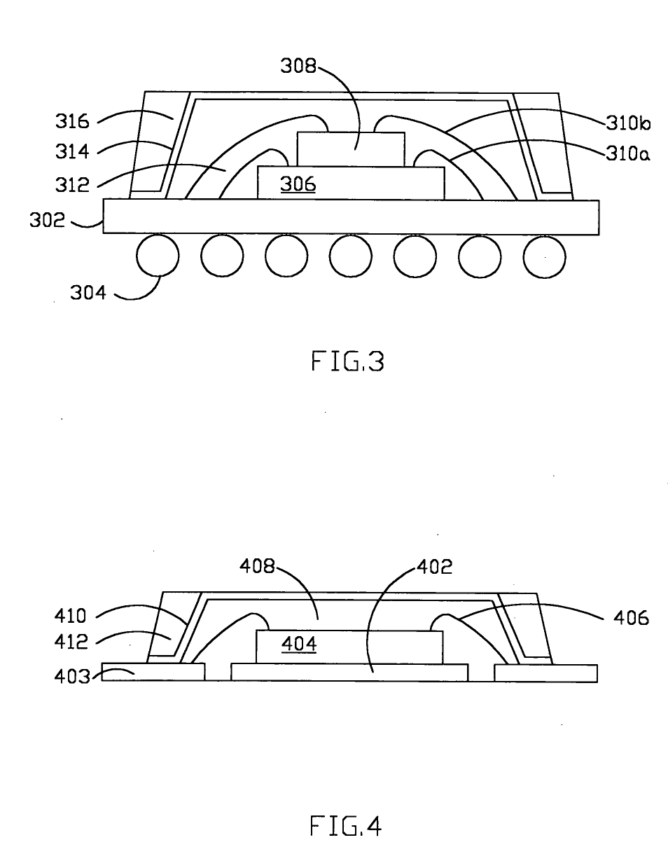

As shown in FIG. 3, represents.. a third embodiment of the present invention. FIG. 3 shows a stacked ball grid array (stacked BGA) package structure. The stacked BGA package structure utilizes the die attach epoxy or silver glue to fix the chip 306 on the board 302. Then, the chips 306 and 308 are electrically coupled with the board 302 through the wires 310a and 310b respectively by using the wire bonding. The board 302 has a plurality of solder balls 304 electrically coupled with the printed circuit board (PCB). The board 302 includes a substrate. The chips 306 and 308 can be the chips that are produced by a low k fabrication process. The wires 310a and 310b can be Al-wires or Au-wires. Then, performing a molding process, the board 302, chips 306 and 308 are placed in the mold. Then, an inner molding compound is filled into the mold to form an inner molding compound 312 to cover the chips 306 and 308. In order to release the stress, the inner molding compound is soft and has enough elastic modulus, in which the material of the inner molding compound 312 is TIM (thermal interface material), and the modulus of the inner molding compound 312 is between 0.4 Mpa and 12 Mpa. Next, a heat sink 314 is placed on the inner molding compound 312, in which the heat sink 314 includes an Al-heat sink or a Cu-heat sink. Then, an outer molding compound is formed around the heat sink 314 to form an outer molding compound 316 as shown in FIG. 3. The outer molding compound 316 has enough strength, hardness, and the modulus, in which the modulus is between 35000 Mpa and 16000 Mpa, and the material of the outer molding compound 316 is epoxy. The material request for the inner/outer molding compound (312/316) is that the modulus of the outer molding compound 316 is larger than the modulus of the inner molding compound 312. Furthermore, in this embodiment of the present invention, the outer molding compound 316 can be optional during the packaging process. However, the heat sink 314 should be fixed by using the adhesive when the outer molding compound 316 is omitted.

As shown in FIG. 4, represents a fourth embodiment of the package structure of the present invention. FIG. 4 shows a quad flat package (QFP) non-leaded package structure. The QFP non-leaded package structure utilizes the die attach epoxy or silver glue to fix the chip 404 on the die pad 402. The input/output pads of the chip 404 are electrically coupled with the pins 403 of the board (not shown) through the wires 406 by the wire bonding. The board includes a leadframe which has a die pad 402 and the pins 403. The chip 404 includes a first chip that is produced by a low k fabrication process. The wires 406 can be Al-wires or Au-wires. Then, performing a molding process, the die pad 402 and chip 404 are placed into the mold. The inner molding compound is filled into the mold to form an inner molding compound 408 to cover the chip 404 as shown in FIG. 4. In order to release the stress, the inner molding compound 408 is soft and has enough elastic modulus, in which the material of inner molding compound 408 is thermal interface material (TIM), and the modulus of inner molding compound 408 is between 0.4 Mpa and 12 Mpa. Next, a heat sink 410 is located outside the inner molding compound 408, in which the heat sink 410 includes an Al-heat sink or a Cu-heat sink. Then, an outer molding compound is formed around the heat sink 410 to form an outer molding compound 412 as shown in FIG. 4. The outer molding compound 412 has enough strength, hardness, and the modulus, in which the modulus is between 35000 Mpa and 16000 Mpa, and the material of the outer molding compound 412 is epoxy. The material request for the inner/outer molding compound (408/412) is that the modulus of the outer molding compound 412 is larger than the modulus of the inner molding compound 408. Furthermore, in this embodiment of the present invention, the outer molding compound 412 is optional during the packaging process. However, the heat sink 410 should be fixed by using the adhesive when the outer molding compound 412 is omitted. As shown in FIG. 5, represents a fifth embodiment of the chip package structure of the present invention. FIG. 5 represents a cavity down ball grid array package structure. The substrate 502 and the chip 504 are fixed on the heat sink 506. The substrate 502 and the heat sink 506 constructed a cavity to contain the chip 504. Next, the input/output pad of the chip 504 is electrically coupled with the substrate 502 through the wires 508 by the wire bonding. The substrate 502 has a plurality of solder balls 516 to electrically couple with the printed circuit board. The board is constituted of the substrate 502 and the heat sink 506. The chip 504 includes a first chip that is produced by a low k fabrication process. The wires 508 can be Al-wires or Au-wires. Then, performing a molding process, the inner molding compound is covered the chip 504 and wires 508 to form an inner molding compound 510. Similarly, in order to release the stress, the inner molding compound 510 is soft and has enough elastic modulus, in which the material of the inner molding compound 510 is thermal interface material (TIM), and the modulus is between 0.4 Mpa and 12 Mpa. Next, a heat sink 512 is located outside the inner molding compound 510, in which the heat sink 512 includes an Al-heat sink or a Cu-heat sink. Then, an outer molding compound is formed around the heat sink 512 to form an outer molding compound 514. The outer molding compound 514 has enough strength, hardness, and the modulus, in which the modulus is between 35000 Mpa and 16000 Mpa, and the material of the outer molding compound 514 is epoxy. The material request for the inner/outer molding compound (510/514) is that the modulus of the outer molding compound 514 is larger than the modulus of the inner molding compound 510. Furthermore, the outer molding compound 514 is optional during the cavity down ball grid array packaging process. However, the heat sink 512 should be fixed on the substrate 502 by using the adhesive when the outer molding compound 514 is omitted.

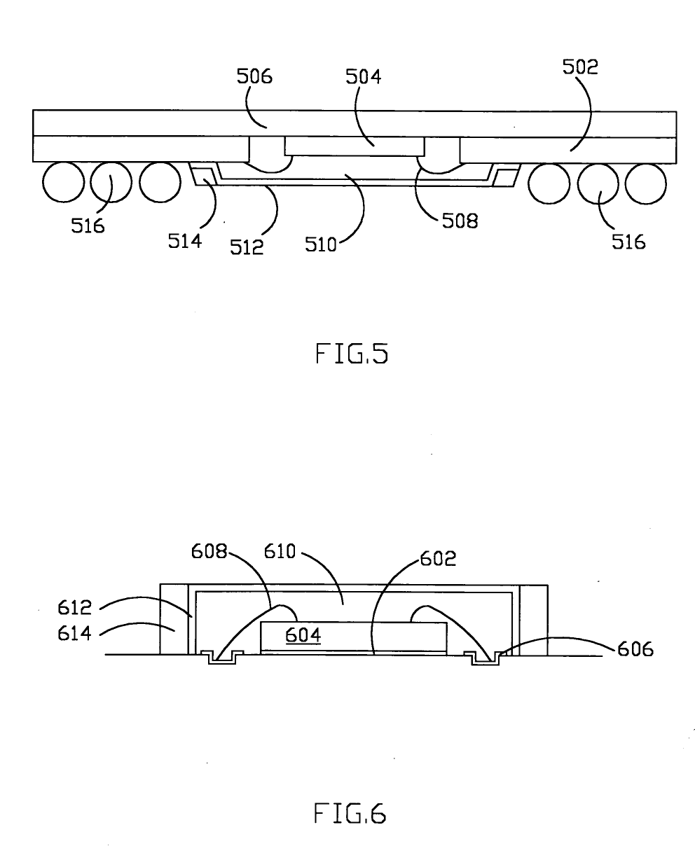

As shown in FIG. 6, represents the sixth embodiment of the package structure of the present invention. FIG. 6 shows a bump chip carrier (BCC) package structure. The BCC package structure utilizes the glue layer 602 to fix the chip 604 on a metal plate (not shown). Then, the chip 604 is electrically coupled with the metal electrodes 606 on the metal plate through the wires 608 by the wire boding. The glue layer 602 includes die attach epoxy or silver glue. The chip 604 includes the first chip that is produced by a low k fabrication process. The wires 608 can be Al-wires or Au-wires. Next, performing a molding process, the chip 604 is placed in the mold, and the inner molding compound is filled into the mold to form an inner molding compound 614 to cover the chip 604 as shown in FIG. 6. In order to release the stress, the inner molding compound 610 is soft and has enough elastic modulus, in which the material of the inner molding compound 610 is TIM (thermal interface material), and the modulus of the inner molding compound 610 is between 0.4 Mpa and 12 Mpa. Next, a heat sink 612 is placed on the inner molding compound 610, in which the heat sink 612 includes an Al-heat sink or a Cu-heat sink. Then, an outer molding compound is formed around the heat sink 612 to form an outer molding compound 614. Thereafter, performing an etching process to remove the metal plate to remain the metal electrodes 606, or remain the metal electrodes 606 and the exposed die pad (not shown). Thus, the metal electrodes 606, or both the metal electrodes and the exposed die pad are electrically coupled with the outer circuit such as printed circuit board to form the bump chip carrier (BCC). The outer molding compound 614 has enough strength, hardness, and the modulus, in which the modulus of the outer molding compound 614 is between 35000 Mpa and 16000 Mpa, and the material of the outer molding compound 614 is epoxy. The material request for the inner/outer molding compound (610/614) is that the modulus of the outer molding compound 614 is larger than the inner molding compound 610. Furthermore, the outer molding compound 614 is optional during the bump chip carrier packaging process. However, the heat sink 612 should be fixed on the substrate by using the adhesive when the outer molding compound 614 is omitted.

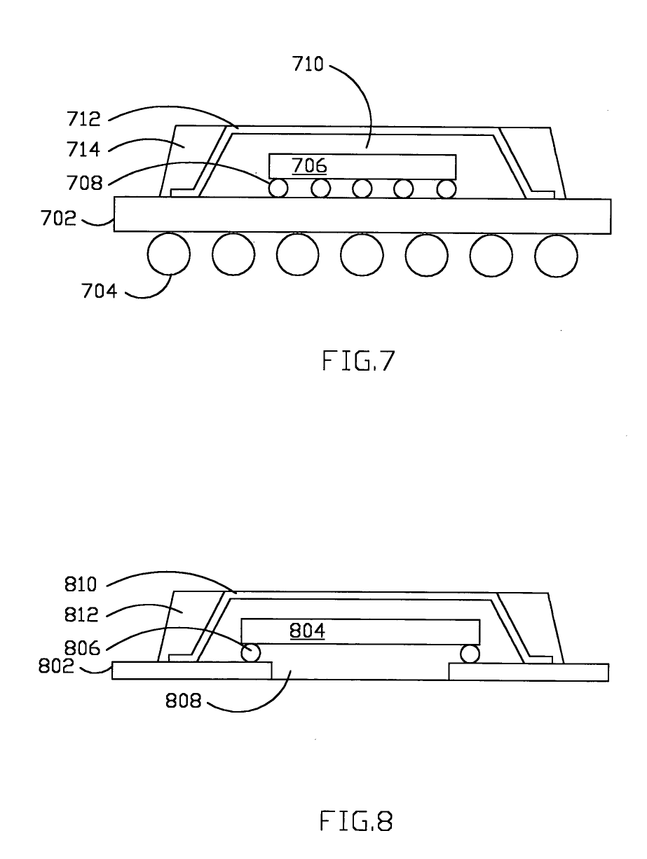

As shown in FIG. 7, represents the seventh embodiment of the chip package structure of the present invention. FIG. 7 shows a flip chip ball grid array (FCBGA) package structure. The chip 706 has multitudes of solder bumps 708 on an active surface. The active surface of the chip 706 is placed downward to electrically couple the metal pad (for example, Cu pad) of the board 702 through the solder bumps 708. The board 702 includes a substrate. The chip 706 includes a first chip that is produced by a low k fabrication process. The material of the solder bump is not only the Pb—Sn alloy, but also without Pb that could be utilized in the packaging process. The board 702 has a plurality of solder balls 704 to electrically couple the printed circuit board. Then, performing a molding process, the inner molding compound is filled into the mold to form an inner molding compound 710 to cover the chip 706 as shown in FIG. 7. Similarly, in order to release the stress, the inner molding compound 710 is soft and has enough elastic modulus, in which the material of the inner molding compound 710 is TIM (thermal interface material), and the modulus of the inner molding compound 710 is between 0.4 Mpa and 12 Mpa. Next, a heat sink 712 is formed on the inner molding compound 710, in which the heat sink 712 includes an Al-heat sink or a Cu-heat sink. Then, an inner molding compound is formed around the heat sink 712 to form an outer molding compound 714 as shown in FIG. 7. The outer molding compound 714 has enough strength, hardness, and the modulus, in which the modulus of the outer molding compound 714 is between 35000 Mpa and 16000 Mpa, and the material of the outer molding compound 714 is epoxy. The material request for the inner/outer molding compound (710/714) is that the modulus of the outer molding compound 714 is larger than the inner molding compound 710. Furthermore, the outer molding compound 714 is an optional during the FCBGA packaging process. However, the heat sink 712 should be fixed on the substrate by using the adhesive when the outer molding compound 714 is omitted.

As shown in FIG. 8, represents the eighth embodiment of the chip package structure of the present invention. FIG. 8 shows a flip chip quad flat non-leaded (FCQFN) package structure. The active surface of the chip 804 is placed downward to bond the pins 802 through the solder bump 806. The chip 804 includes a first chip that is produced by a low k fabrication process. Then, performing a molding process, the inner molding compound is filled into the mold to form an inner molding compound 808 to cover the chip 804 as shown in FIG. 8. The inner molding compound 808 is filled with the space adjacent the pins 802. In order to release the stress, the inner molding compound 808 is soft and has enough elastic modulus, in which the material of the inner molding compound 808 is TIM (thermal interface material), and the modulus of the inner molding compound 808 is between 0.4 Mpa and 12 Mpa. Then, a heat sink 810 is placed on the inner molding compound 808, and the heat sink 810 includes an Al-heat sink or a Cu-heat sink. Next, an outer molding compound is formed around the heat sink 810 to form an outer molding compound 812. The outer molding compound 812 has enough strength, hardness, and the modulus, in which the modulus is between 35000 Mpa and 16000 Mpa, and the material of the outer molding compound 812 is epoxy. The material request of the inner/outer molding compound (808/812) is that the modulus of the outer molding compound 812 is larger than the modulus of the inner molding compound 808. Furthermore, the outer molding compound 812 is optional during the FCQFN packaging process. However, the heat sink 810 should be fixed on the substrate by using the adhesive when the outer molding compound 812 is omitted.

Although specific embodiments have been illustrated and described, it will be obvious to those skilled in the art that various modifications may be made without departing from what is intended to limit solely by the appended claims.

1. A chip package structure, said chip package structure comprising:
a board;
a first chip on said board, wherein said first chip has a plurality of first conductors electrically coupling with said board and said first chip;
an inner molding compound covering said first chip and said first conductors; and
a first heat sink covering said inner molding compound and fixed on a first surface of said board.

2. The chip package structure according to claim 1, further comprising an outer molding compound formed around said first heat sink, wherein the modulus of said outer molding compound is larger than the modulus of said inner molding compound.

3. The chip package structure according to claim 1, wherein said board has a plurality of solder balls constructing a ball grid array package structure are on a second surface of said board that is opposite to said first surface.

4. The chip package structure according to claim 1, wherein the modulus of said inner molding compound is between 0.4 Mpa and 12 Mpa.

5. The chip package structure according to claim 1, further comprising a second chip on said first chip, wherein said second chip has a plurality of second conductors electrically coupling with said board and said second chip.

6. The chip package structure according to claim 2, wherein the material of said outer molding compound is epoxy.

7. The chip package structure according to claim 2, wherein the modulus of said outer molding compound is between 35000 Mpa and 16000 Mpa.

8. The chip package structure according to claim 1, wherein said first chip is produced by a low dielectric (low k) fabrication process.

9. The chip package structure according to claim 1, wherein said board is one of a circuit substrate and a leadframe.

10. The chip package structure according to claim 1, wherein said board is a leadframe, and said chip package structure is a quad flat package structure.

11. The chip package structure according to claim 1, wherein said board is a leadframe, and said chip package structure is a quad flat package non-leaded package structure.

12. The chip package structure according to claim 1, wherein said board comprises a second heat sink adhering on a substrate to form a cavity for containing said chip, and said chip package structure further comprised a plurality of solder balls on a surface of said substrate for structurally and electrically coupling with a printed circuit board.

13. The chip package structure according to claim 1, wherein said first conductors comprise a plurality of solder bumps for mechanically and electrically coupling said first chip with said board by using flip chip.

14. The chip package structure according to claim 1, wherein said first conductors comprise a plurality of first wires.

15. The chip package structure according to claim 1, wherein said board is a leadframe, and said first chip is mechanically and electrically coupled with said leadframe through a plurality of solder bumps to form a flip chip quad flat non-leaded package structure.

16. A chip package structure, said chip package structure comprising:
a chip electrically coupled with a plurality of metal electrodes through a plurality of wires;
an inner molding compound covering said chip, said wires and a first surface of said metal electrodes and having a portion exposing a second surface of said metal electrodes, said second surface opposite to said first surface and configured for electrically coupling an outer circuit; and
a heat sink covering a surface of said inner molding compound exclusive of electrically coupling with said portion of said outside circuit.

17. The chip package structure according to claim 16, further comprising an outer molding compound formed around said heat sink, wherein the modulus of said outer molding compound is larger than the modulus of said inner molding compound.

18. The chip package structure according to claim 16, wherein the material of said inner molding compound is ABLETHERM 3185 (RP-507-30).

19. The chip package structure according to claim 17, wherein the material of said outer molding compound is epoxy.

20. The chip package structure according to claim 16, wherein the modulus of said inner molding compound is between 500 Mpa and 16000 Mpa.

21. The chip package structure according to claim 17, wherein the modulus of said outer molding compound is between 35000 Mpa and 16000 Mpa.

22. The chip package structure according to claim 16, wherein said chip is produced by a low dielectric (low k) fabrication process.

23. The chip package structure according to claim 16, further comprising a die attached pad on said portion of said inner molding compound, and said die attached pad coupled with said chip through a glue layer.
